(19) United States
(12) Patent Application Publication
(10) Pub. No.: US 2002/0182338 A1
(43) Pub. Date: Dec. 5, 2002

(54) Apparatus and method for rotating drum chemical bath deposition

(76) Inventors: John Stevens, Larkspur, CO (US); Leon B. Fabick, Denver, CO (US)

Correspondence Address: MCKENNA & CUNEO, LLP, 1900 K Street, NW, Washington, DC, 20006, US

(21) Appl. No.: 10/160,193

(22) Filed: Jun. 4, 2002

Related U.S. Application Data
(60) Provisional application No. 60/295,014, filed on Jun. 4, 2001.

(51) Int. Cl. C23C 16/00; H01F 41/00; B01J 19/08; G21H 5/00

(52) U.S. Cl. 427/457; 118/730; 118/722

(57) ABSTRACT

The present invention relates to a novel method and apparatus for chemical bath deposition or other plating or similar processes. The deposition may be performed in a rotating drum that has been provided with a mechanism for temperature elevation. A substrate or other suitable recipient bed upon which deposition is sought may be removably attached to the interior of the drum. Reactants or other materials may be added to the drum to deposit a film, layer, or uniform particles on the surface of the substrate.

### CROSS REFERENCE TO RELATED APPLICATIONS

The present application is related to and claims, under 35 U.S.C. §119(e), the benefit of U.S. Provisional Patent Application Serial No. 60/295,014, filed Jun. 4, 2001, which is incorporated herein by reference.

### BACKGROUND OF THE INVENTION

1. Field of the Invention

The present invention relates to the chemical bath deposition of thin films or layers of particles of materials on substrates or other recipient beds by means of a rotating drum. The method and apparatus described yield a uniform thin film or layer of a deposited chemical on the underlying substrate. In particular this specification also describes, as an example, an embodiment of the invention relating to the deposition of cadmium sulfide on a photovoltaic absorber layer.

2. Description of the Prior Art

Techniques for deposition of films include the following: sputtering, vacuum evaporation, chemical vapor deposition, chemical bath deposition (CBD), spray pyrolosis, printing and sintering, thermal decomposition of a metal organic compound, and similar related methods (see, for example, U.S. Pat. No. 6,211,043). The chemical bath deposition method is easily illustrated by the deposition of cadmium sulfide on a photovoltaic absorber layer. The prior art method of chemical bath deposition of cadmium sulfide (CdS) begins with a solution of cadmium sulfate (CdSO₄) or some other salt of Cadmium such as cadmium acetate, cadmium nitrate, and cadmium chloride, and ammonium hydroxide (NH₄OH). Such a solution is referred to as a chemical bath. A substrate consisting of a photovoltaic absorber layer is inserted into the chemical bath. Next, a solution of thiourea, a reagent, is added to the chemical bath. The temperature of the chemical bath is elevated to 70 degrees Celsius. While the temperature is rising the mixture reacts and deposits CdS onto the surfaces contained in the reaction vessel. The CdS layer forms a junction between positive and negative charge carriers (a p/n junction) with the photovoltaic absorber. During the reaction a precipitate of CdS forms. The reaction continues until it depletes the constituent reactants. The completion of this reaction and deposition is followed by the complete replacement and disposal of the solutions used in this process. The discarded solution must be treated as hazardous, cadmium-containing waste. In a large scale production environment, this process consumes a large amount of chemicals, and results in a large amount of waste. Additionally, the large amounts of reactants used take a long time to heat to the necessary temperature to produce the reaction. This increased heating time further decreases the efficiency of the process in larger scale production, while imposing high energy demands and thus higher costs.

### SUMMARY OF THE INVENTION

The present invention solves the problem of needing large amounts of chemicals and producing large amounts of hazardous waste for chemical bath deposition, while providing for the necessary reaction to occur quickly and more uniformly, reducing energy demands and reducing costs. In one embodiment of the present invention, a drum capable of rotation may be immersed in a bath. Preferably, this bath is water or another liquid or gas capable of heat transfer, and preferably this immersion is as complete as possible. In the alternative, the drum may be heated by radiation, using, for example, a quartz-halogen bulb. The drum is preferably a hollow right regular cylinder, but may be any suitable shape for containing a material and a liquid or vapor for subsequent deposition process. The drum is preferably constructed of a glass, metal, ceramic, composite or equivalent material capable of containing a fluid and withstanding the rotational and thermal loads of the deposition process. If desired, the interior surface of the drum may be coated with a material adapted to reduce the amount of deposition onto the interior surface of the drum. An example of such a material is Teflon. A substrate or similar recipient platform may be placed in the interior of the drum. This substrate may, for example, comprise a photovoltaic absorber or Copper-Indium-Gallium-DiSelinide (CIGS) device, but may comprise any substrate or recipient bed. A flexible or easily deformable substrate, however, is preferable because it best conforms to the interior of a drum, and because it will least disturb the flow of reactants within the drum. Moreover a flexible substrate will permit the introduction of a larger piece of continuous substrate, which may be desirable for some applications. Preferably this substrate may be fixed to the interior of the drum. The means for fixing may, for example, comprise a mild adhesive, such as, for example, Kapton tape. Preferably the means for fixing should not interfere with the flow of reactants over the substrate. Additionally, the substrate should preferably not overlap itself.

The drum may be oriented such that its major axis is horizontal. Any suitable mechanism for rotating the drum about an axis, preferably its major axis, may be provided. One method by which this rotation may be accomplished is by means of two or more rollers. These rollers can be made of any acceptable material designed to handle the rotational load of the drum, including metal, acrylic, ceramic and other composite or equivalent materials. One or more of the rollers may provide support and another may produce rotation of the of the drum through friction with a surface of the drum. It is preferred that this surface be an exterior surface. Preferably the drum may be rotated at about 4 to 30 revolutions per minute. Another suitable rotation mechanism may be any appropriate rotatable axle or motor affixed to the drum by any means to transfer the rotation of the axle or motor to the drum. For example, a motor can be rotatably connected to a drum suitably resting on rollers or suspended from a mechanical frame, free from rotational interference. Alternatively a belt may be affixed around the drum or a gearing mechanism may be attached to the drum to interface with a motor and gear mechanism.

In this example, through one or more ends of the drum a pipe, tube, or conduit may be placed to permit the introduction of the reactants into the drum. To aid in the introduction of the reactants, a funnel may preferably be attached to the pipe or pipes. The bath preferably is heated by a heating mechanism to ensure that its temperature remains at the desired temperature. This desired temperature may, for example, be the reaction temperature of the reactants. In the specific example of CdS, the reaction temperature is preferably approximately 40 to 70 degrees Celsius. One skilled in the art will know what temperature will result in a desired reaction for a given coating chemical. The method of manufacture of this conduit may preclude immersing the drum beyond the level of the conduit, as such immersion might result in the entry of water or other heating medium into the drum, and such entry may be undesirable.

The rotating drum allows a smaller amount of reactant to be used, in comparison to the prior art, which facilitates a quicker time to reaction, less energy input, and lower amounts of chemicals used and waste created. Additionally, the rotating drum reduces the need for an additional agitator and ensures a homogeneous mixture, so that each portion of the substrate receives a uniform coating. Moreover, although cleaning the drum after use may require etching with HCl, rinsing with water may, for example, suffice to prepare the drum for the next use.

It is an object of certain embodiments of the present invention to provide a method and apparatus for deposition processes that requires a smaller amount of chemicals. This object is accomplished, for example, by use of a rotating drum. The rotation of the drum allows the precipitate of the reactants to be deposited more nearly solely on substrate, instead of on the reaction vessel or wasted with a large collection vessel as in the prior art. It is a further object of certain embodiments of the invention to provide a method and apparatus that produce less hazardous waste. The uniform deposition of the precipitate of the reactants using a reduced amount of chemicals accomplishes this object. It is a further object of certain embodiments of this invention to reduce the amount of time required to perform the deposition. The smaller amount of chemicals required necessarily requires a smaller amount of thermal energy transfer to accomplish a temperature elevation, thus less energy is expended, and the heating time is decreased. It is a further object of certain embodiments of the present invention to provide a method and apparatus that produce a uniform deposition of layers or particles. The present invention accomplishes this object by providing a uniform and uninterrupted even flow of reactants across the surface of the substrate. The deposition is consequently uniform.

It is understood that both the foregoing general description and the following detailed description are exemplary and explanatory only and are not restrictive of the invention as claimed. The invention is described, for example, in terms of a cadmium sulfide deposition process, however, one skilled in the art will recognize that other chemicals may be deposited on other substrates using the same method and apparatus. For example, lead sulfide may be deposited on a similar photovoltaic absorber layer which has been optimized to absorb radiation in the infrared spectrum. The reaction temperature and the optimal rotation speed will vary, but will be apparent to one skilled in the art. Additionally, although this invention is described in terms of chemical bath deposition, one skilled in the art will recognize other uses for this invention, such as, for example, various plating or etching processes. The accompanying drawings illustrating an embodiment of the invention and together with the description serve to explain the principles of the invention.

### BRIEF DESCRIPTION OF THE DRAWINGS

FIG. 1 is a flow diagram of a preferred embodiment of the method of the present invention.

FIG. 2 is a flow diagram of another preferred embodiment of the method of the present invention.

FIG. 3 is a side cutaway view diagram of a preferred embodiment of the apparatus of the present invention.

FIG. 4 is a top cutaway view diagram of a preferred embodiment of the apparatus of the present invention.

FIG. 5 is an end cutaway view diagram of a preferred embodiment of the apparatus of the present invention.

### DETAILED DESCRIPTION OF THE PREFERRED EMBODIMENTS

It is to be understood that the present invention is not limited to the particular methodology, compounds, materials, manufacturing techniques, uses, and applications, described herein, as these may vary. It is also to be understood that the terminology used herein is used for the purpose of describing particular embodiments only, and is not intended to limit the scope of the present invention. It must be noted that as used herein and in the appended claims, the singular forms “a,” “an,” and “the” include the plural reference unless the context clearly dictates otherwise. Thus, for example, a reference to “a substrate” is a reference to one or more substrates and includes equivalents thereof known to those skilled in the art.

Unless defined otherwise, all technical and scientific terms used herein have the same meanings as commonly understood by one of ordinary skill in the art to which this invention belongs. Preferred methods, techniques, devices, and materials are described, although any methods, techniques, devices, or materials similar or equivalent to those described herein may be used in the practice or testing of the present invention. All references cited herein are incorporated by reference herein in their entirety.

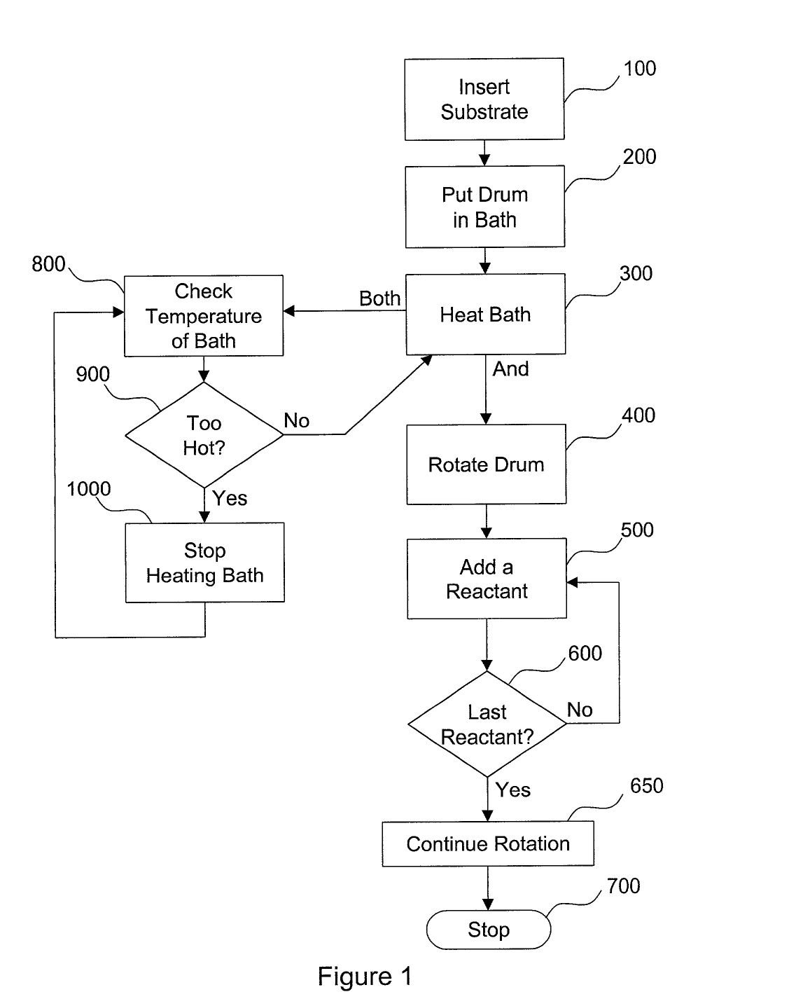

One preferred embodiment of the present invention, diagrammed in FIG. 1, provides a method of chemical bath deposition. This method may begin by placing a substrate inside a hollow drum of any acceptable shape or size (100). This may, for example, be accomplished by using Kapton tape to fix the substrate to the interior of the drum. Next, the drum may be placed in a bath (200). Alternatively, the drum may already be in the bath before the insertion step is accomplished. This bath may preferably comprise water, or may comprise any fluid or gas suitable for the uniform transfer of heat to the drum and its contents. The drum may be immersed in the bath as much as is desired. Next, the bath may be heated to the desired temperature (300). This temperature may be the desired reaction temperature. The drum may then be rotated in the bath (400). This rotation may help the drum to become uniform in temperature. The drum may also begin rotation (400) prior to heating (300). Next, a reactant may be added to the interior of the drum (500). Alternatively, if acceptable for the given process, the reactant may be added earlier. After step 500, it may then be necessary to determine whether any additional reactants are required (600). If so, then the step of adding the reactant (500) and the step of determining whether any additional reactants are needed (600) may be repeated. If not, the drum may be rotated as the desired reaction takes place (650). When suitable deposition has occurred the process may be terminated (700). Throughout the rotation and the addition of the reactants, the temperature of the bath may be measured by, for example, a thermometer (800). One may then decide whether the temperature is too high (900). If the temperature is too high one may stop heating the bath (1000). Otherwise, one may continue to heat the bath (300). In either case, one may continue to monitor the temperature (800) and decide whether the temperature is too high (900). The amount of deposition occurring in the drum may be predicted or monitored with appropriate chemical or electrical sensors or other appropriate visual, mechanical or equivalent device or process.

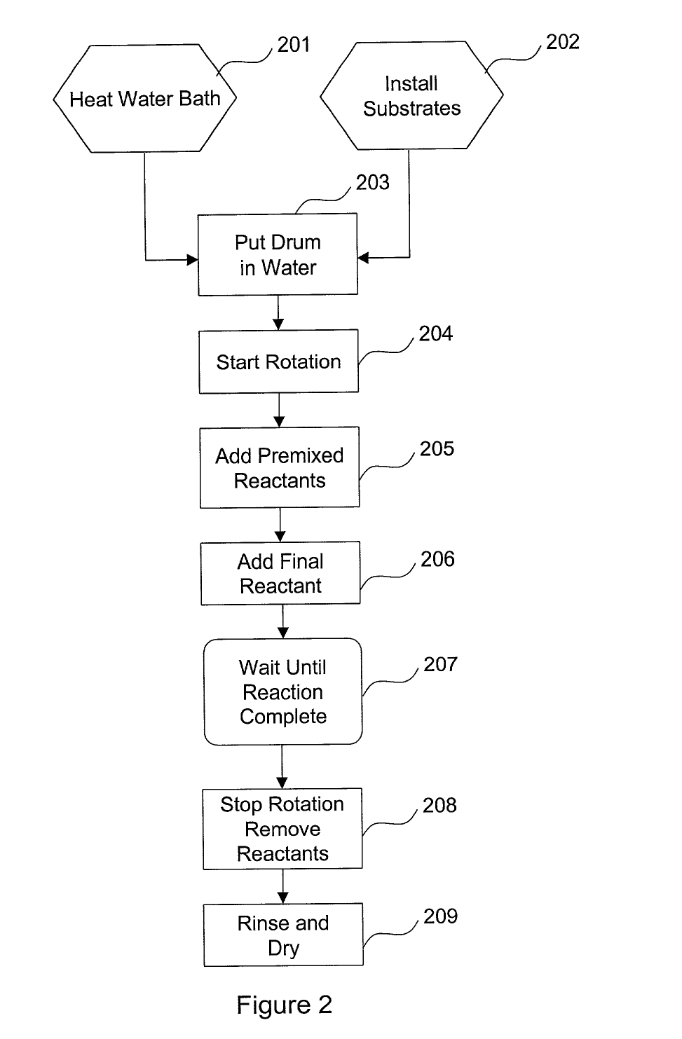

Another preferred embodiment of the present invention is diagrammed in FIG. 2. In this embodiment, the bath may be heated (201) while or before the substrates are being installed into the drum (202). The drum may then be placed in the bath (203) and rotation of the drum may begin (204). A solution of Cadmium Sulfate and Ammonium Hydroxide or other appropriate reactants or materials may then be added (205). Next, the solution of thiourea or other appropriate materials or reactants may be added (206). The reaction may continue until completion or until the desired thickness of deposition is accomplished (207). The rotation of the drum may then be stopped and the reactants and/or waste materials removed (208). Finally the product may be rinsed and dried (209).

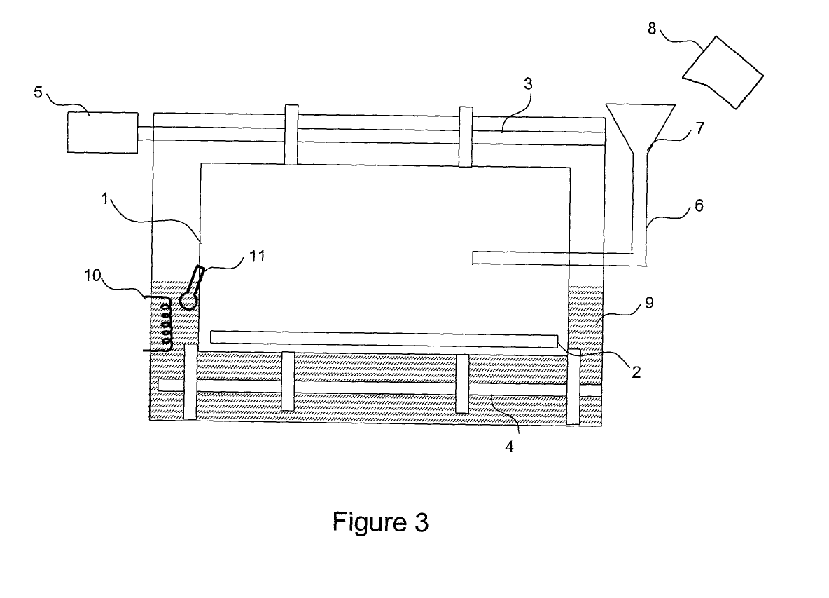

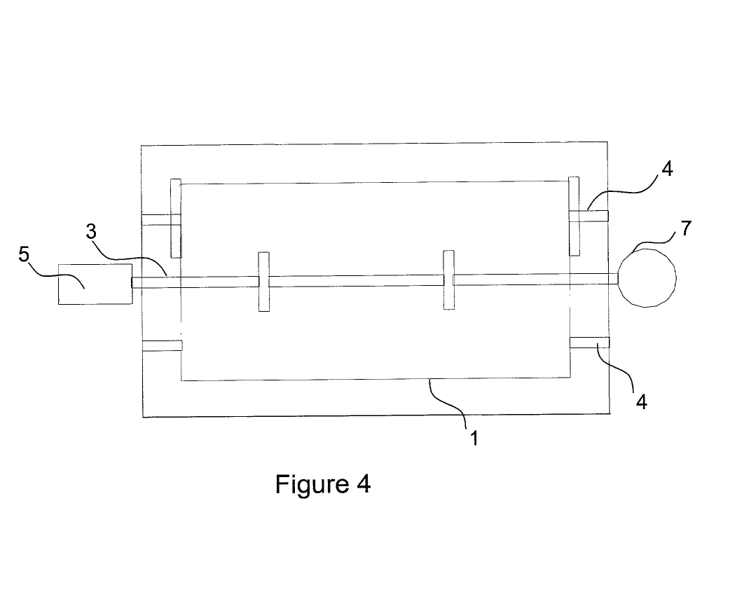

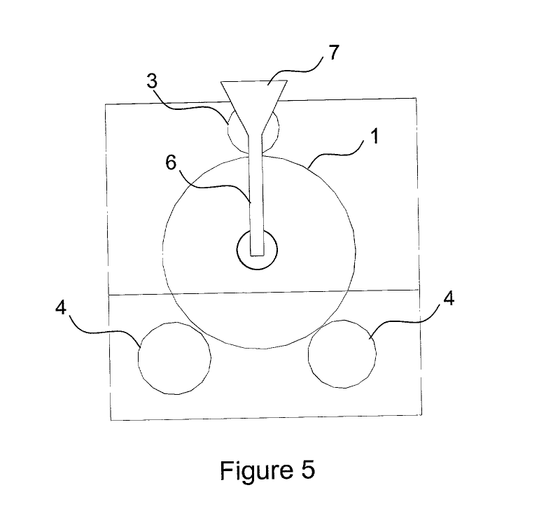

A preferred embodiment of the present invention, depicted in FIGS. 3, 4, and 5, is an apparatus for chemical bath deposition. This apparatus may comprise a drum capable of rotation (1). Preferably, in this example, a cylindrical drum is depicted. Other embodiments of drums may include spheres, ellipsoidal shapes, cones, or any appropriate configuration for the process and recipient bed being treated. A substrate or recipient bed (2) may be placed in this drum (1). Preferably, this substrate (2) may be fixed to the interior of the drum (1) using any acceptable fixation device, such as, a mild adhesive, preferably, for example, Kapton tape. The drum (1) may be placed in a bath (9) at the appropriate level of immersion. This bath (9) preferably comprises water, but can be any acceptable medium capable of uniformly transferring heat to the drum (1). Beneath the drum (1), supporting and allowing rotation may be a pair of rollers (4). A third roller (3) may be located above the drum (1), providing rotation by means of frictional contact with the surface of the drum (1). This third roller (3) may preferably be connected to a motor (5). Alternatively, the motor (5) may be rotatably attached directly to the drum (1) in a manner to accomplish the rotation of the drum (1). Alternatively, motor (5) may be indirectly connected to the drum (1) by means of a belt, pulley, or gears. The drum (1) may permit the entry of chemicals via a conduit (6). This conduit (6) may preferably be in fluid communication with the drum (1) at the geometric center of one of its ends. The conduit (6) may be in fluid communication with a funnel (7). The funnel (7) may aid in the introduction of reactants (8) into the drum (1). One may also provide a mechanism for measuring temperature, such as a thermometer (11) affixed in any appropriate location. The thermometer (11) may, for example, be suspended in the water bath (9). Additionally, a visual, electrical, thermal, chemical, or mechanical sensor may be added to monitor the deposition process. The bath (9) may be heated to a desired temperature by a heating means, such as, for example, a heating coil (10).

Other embodiments of the invention will be apparent to those skilled in the art from consideration of the specification and the practice of the invention disclosed herein. It is intended that the specification and examples be considered as exemplary only, with a true scope and spirit of the invention being indicated by the following claims.

What is claimed is:

1. An apparatus for chemical deposition comprising
a bath, and further comprising
a means for holding and rotating a substrate located in said bath.

2. The apparatus of claim 1 wherein said bath comprises water.

3. The apparatus of claim 1 further comprising means for heating said bath.

4. The apparatus of claim 1 further comprising means for measuring temperature of said bath.

5. The apparatus of claim 1 wherein said means for holding and rotating comprises a hollow drum.

6. The apparatus of claim 1 further comprising a substrate removably connected to the interior of said means for holding and rotating.

7. The apparatus of claim 1 wherein said means for holding and rotating a substrate is adapted to receive a substrate removably connected to its interior surface.

8. The apparatus of claim 1 wherein said means for holding and rotating a substrate is adapted to receive the introduction of chemical reactants.

9. The apparatus of claim 1 wherein said means for holding and rotating a substrate is adapted to be heated to at least 70 degrees Celsius.

10. The apparatus of claim 5 wherein said drum is a hollow, right, regular cylinder.

11. The apparatus of claim 5 wherein said drum has a major axis and said drum is oriented so that its major axis is horizontal.

12. The apparatus of claim 11 wherein said drum is rotated about its major axis.

13. The apparatus of claim 5 wherein said drum is rotated by means of a plurality of rollers.

14. The apparatus of claim 5 wherein said drum is adapted to be rotated by a motor.

15. The apparatus of claim 13 wherein said rollers comprise a support roller and a driving roller.

16. The apparatus of claim 5 further comprising a conduit on said drum for the introduction of said reactants into said drum.

17. The apparatus of claim 16 wherein said drum has an end, and said conduit is in fluid communication with said drum through one said end of said drum.

18. The apparatus of claim 17 wherein said conduit is in fluid communication with said drum through the center of said drum end.

19. The apparatus of claim 16 further comprising a funnel in fluid communication with one end of the conduit.

20. The apparatus of claim 13 wherein said drive roller is connected to a motor.

21. The apparatus of claim 12 wherein said drum is adapted to be rotated between about 4 and 30 revolutions per minute.

22. The apparatus of claim 8 wherein said reactants comprise a Cadmium Sulfate solution.

23. The apparatus of claim 8 wherein said reactants comprise an Ammonium Hydroxide solution.

24. The apparatus of claim 8 wherein said reactants comprise a thiourea solution.

25. The apparatus of claim 5 wherein said substrate is removably connected to the interior perimeter of said drum.

26. The apparatus of claim 25 wherein said substrate is flexible.

27. The apparatus of claim 25 wherein said substrate is a photovoltaic absorber layer.

28. A method of depositing material on a recipient bed comprising the steps of
placing a substrate into a drum;
conditioning said drum to a desired temperature;
introducing reactants into said drum; and
rotating said drum.

29. The method of claim 28 further comprising placing said drum into a bath to heat it to a desired temperature.

30. The method of claim 28 wherein said substrate is a flexible substrate.

31. The method of claim 28 wherein said substrate comprises a photovoltaic absorber layer.

32. The method of claim 28 wherein said placing said substrate into said drum further comprises placing said substrate at the interior perimeter of said drum.

33. The method of claim 28 wherein said placing said substrate into said drum further comprises removably attaching said substrate to said drum.

34. The method of claim 29 wherein said bath comprises water.

35. The method of claim 28 wherein said desired temperature is the reaction temperature of said reactants.

36. The method of claim 35 wherein said reaction temperature is 70 degrees Celsius.

37. The method of claim 28 wherein said reactants are introduced through a conduit.

38. The method of claim 37 wherein said conduit is in fluid communication with an end of said drum.

39. The method of claim 38 wherein said conduit is in fluid communication with the center of said end of said drum.

40. The method of claim 37 wherein said conduit is in fluid communication with a funnel.

41. The method of claim 28 wherein the reactants comprise a solution of Cadmium Sulfide.

42. The method of claim 28 wherein the reactants comprise a solution of Ammonium Hydroxide.

43. The method of claim 28 wherein the reactants comprise a solution of thiourea.

44. The method of claim 28 wherein said rotation is about the major axis of the drum.

45. The method of claim 28 wherein said rotation is constant and uniform.

46. The method of claim 28 wherein said rotation is approximately 20 to 30 revolutions per minute.

47. The method of claim 28 wherein said introduction of reactants comprises a first step of adding a first reactant, and a second step of adding a second reactant.

48. The method of claim 47 further comprising the step of waiting for the first reactant to heat before adding a second reactant.

49. The method of claim 28 wherein the chemical to be deposited is selected from the group consisting of cadmium sulfide, zinc sulfide, lead sulfide, copper sulfide, mercury sulfide, or indium sulfide.

50. The method of claim 28 further comprising fixing the substrate to the interior of said drum.
